(19) United States
(12) Patent Application Publication
(10) Pub. No.: US 2023/0328921 A1
(43) Pub. Date: Oct. 12, 2023

(54) COOLING MEMBER

(71) Applicant: Nidec Corporation, Kyoto (JP)

(72) Inventors: Hong Long CHEN, Kyoto (JP); Koji MURAKAMI, Kyoto (JP); Yuki YANAGITA, Kyoto (JP)

(21) Appl. No.: 18/119,864

(22) Filed: Mar. 10, 2023

(30) Foreign Application Priority Data
Mar. 16, 2022 (JP) 2022-040957

(51) Int. Cl. H05K 7/20

(52) U.S. Cl. CPC H05K 7/20254; H05K 7/20409; H05K 7/209; H05K 7/20927

(57) ABSTRACT

A cooling structure includes a base with a plate shape, that extends in a first direction along a refrigerant flow direction and in a second direction perpendicular or substantially perpendicular to the first direction, a thickness of which extending in a third direction perpendicular or substantially perpendicular to the first direction and the second direction, and fins that protrude from the base to one side in the third direction, that extend in the first direction, and that are side by side in the second direction. Each of the fins includes a curved portion that is curved due to a convex portion, protruding to one side in the second direction, and a concave portion, recessed from the other side to the one side in the second direction, located at a same position in the first direction.

### CROSS-REFERENCE TO RELATED APPLICATIONS

The present application claims priority under 35 U.S.C. §119 to Japanese Patent Application No. 2022-040957, filed on Mar. 16, 2022, the entire contents of which are hereby incorporated herein by reference.

### 1. FIELD OF THE INVENTION

The present disclosure relates to a cooling structure.

### 2. BACKGROUND

A cooling member is conventionally used for cooling a heating element. The cooling member includes a base portion, a plurality of columnar fins, and a plurality of plate-shaped fins. The plurality of columnar fins protrude from the base portion toward a flow path of a refrigerant. Each of the plurality of plate-shaped fins extends in a flowing direction of the refrigerant and connects the adjacent columnar fins. It is possible to suppress a decrease in a flow velocity of the refrigerant by the plate-shaped fins, and to improve a cooling performance as compared with a configuration of only the columnar fins.

In the conventional cooling member, it is necessary to connect the columnar fin and the plate-shaped fin by a joining method such as brazing. Thus, when each of the plurality of plate-shaped fins is connected to the columnar fin, there is a problem in that a manufacturing cost increases.

### SUMMARY

A cooling structure according to an example embodiment of the present disclosure includes a base portion that has a plate shape, that extends in a first direction along a refrigerant flow direction and in a second direction perpendicular or substantially perpendicular to the first direction, and that has a thickness in a third direction perpendicular or substantially perpendicular to the first direction and the second direction, and fins that protrude from the base portion to one side in the third direction, that extend in the first direction, and that are arranged side by side in the second direction. Each of the fins includes a curved portion that is curved due to a convex portion, protruding to one side in the second direction, and a concave portion, recessed from another side to the one side in the second direction, at a same position in the first direction.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view of a cooling structure according to an example embodiment of the present disclosure.

FIG. 2 is a side view of the cooling structure of FIG. 1.

FIG. 3 is a plan view of the cooling structure of FIG. 1.

FIG. 4 is a bottom view of the cooling structure of FIG. 1.

FIG. 5 is a partially enlarged cross-sectional view of the cooling structure of FIG. 1.

FIG. 6 is a perspective view of a fin as viewed from one side in a second direction.

FIG. 7 is a partially enlarged perspective view of the fin as viewed from the one side in the second direction.

FIG. 8 is a perspective view of the fin as viewed from the other side in the second direction.

FIG. 9 is a partially enlarged perspective view of the fin as viewed from the other side in the second direction.

FIG. 10 is a partially enlarged cross-sectional view of a cooling structure according to a first modification of an example embodiment of the present disclosure.

FIG. 11 is a partially enlarged cross-sectional view of a cooling structure according to a second modification of an example embodiment of the present disclosure.

FIG. 12 is a partially enlarged cross-sectional view of a cooling structure according to a first comparative example.

FIG. 13 is a partially enlarged cross-sectional view of a cooling structure according to a second comparative example.

FIG. 14 is a partially enlarged cross-sectional view of a cooling structure according to a third comparative example.

FIG. 15 is a graph illustrating a maximum temperature of a heating element of the cooling structure of each of the example embodiment, the modifications, and the comparative examples.

FIG. 16 is a graph illustrating a pressure loss of a refrigerant of a cooling structure of each of an example embodiment, the modifications, and the comparative examples.

FIG. 17 is a graph illustrating the maximum temperature of the heating element when a fin shape of a cooling structure according to an example embodiment of the present disclosure is changed.

FIG. 18 is a graph illustrating the pressure loss of the refrigerant when the fin shape of the cooling structure according to an example embodiment of the present disclosure is changed.

### DETAILED DESCRIPTION

Example embodiments of the present disclosure will be described hereinafter with reference to the drawings. It is to be noted that the scope of the present disclosure is not limited to the following example embodiments, and may be arbitrarily changed within the scope of the technical idea of the present disclosure.

In the present specification, an X direction is defined as a first direction, and an arrow X1 indicating one side in the first direction and an arrow X2 indicating the other side in the first direction are illustrated in the drawings. The first direction X is along a direction in which a refrigerant flows. In addition, a Y direction is defined as a second direction perpendicular or substantially perpendicular to the first direction X, and an arrow Y1 indicating one side in the second direction and an arrow Y2 indicating the other side in the second direction are illustrated in the drawings. Further, a Z direction is defined as a third direction perpendicular or substantially perpendicular to the first direction X and the second direction Y, and an arrow Z1 indicating one side in the third direction and an arrow Z2 indicating the other side in the third direction are illustrated in the drawings. It is to be noted that the above definitions of the directions do not limit an orientation and a positional relationship of a cooling structure at the time of use. Further, “parallel” and “perpendicular or substantially perpendicular” used in the present specification do not represent parallel or perpendicular or substantially perpendicular in a strict sense, and include substantially parallel and substantially perpendicular or substantially perpendicular.

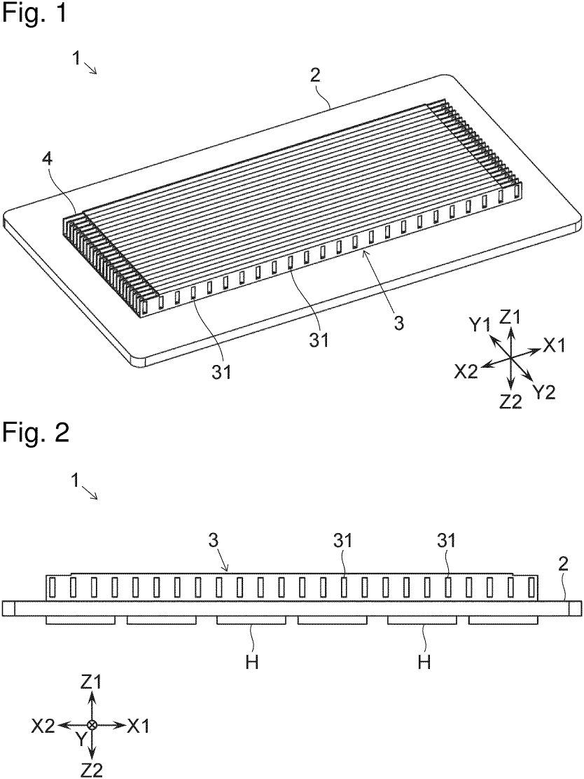

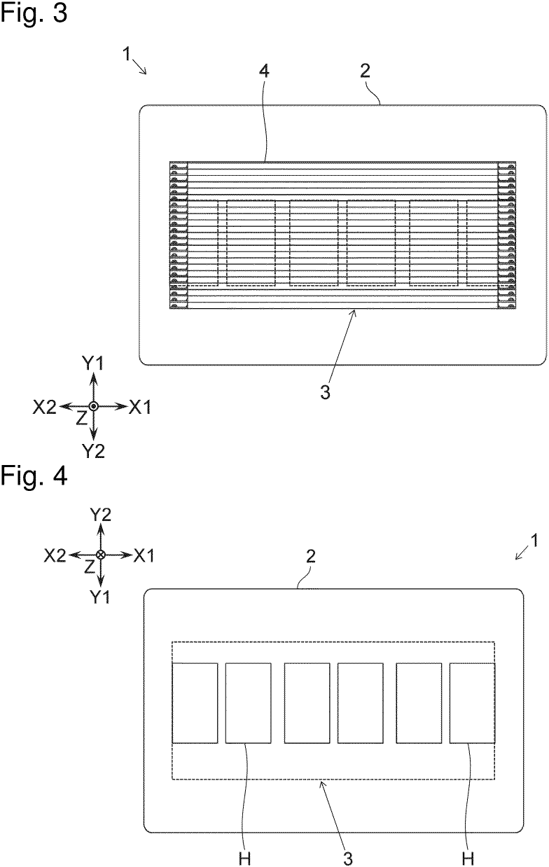

FIG. 1 is a perspective view of a cooling structure 1 according to an example embodiment. FIG. 2 is a side view of the cooling structure 1. FIGS. 3 and 4 are a plan view and a bottom view of the cooling structure 1 respectively.

In the present example embodiment, the cooling structure 1 is a device that is installed in a liquid-cooled jacket not illustrated and that cools a plurality of heating elements H arranged side by side in a first direction X. The heating element H is, for example, a power transistor of an inverter installed in a traction motor for driving wheels of a vehicle. The power transistor is, for example, an insulated gate bipolar transistor (IGBT). In this case, the cooling structure 1 is mounted on the traction motor. It is to be noted that the number of heating elements H may be a plurality other than six illustrated in FIG. 2, or may be one.

The cooling structure 1 includes a base portion 2 and a plurality of fins 3.

The base portion 2 has a plate shape that extends in the first direction X and a second direction Y and that has a thickness in a third direction Z. The base portion 2 is made of metal having high thermal conductivity, and made of, for example, copper.

The plurality of fins 3 are arranged on one surface of the base portion 2 on one side Z1 in the third direction. The plurality of fins 3 protrude from the base portion 2 to the one side Z1 in the third direction and extend in the first direction X. The fin 3 has a plate shape extending in the first direction X and the third direction Z, and is made of metal, for example. The plurality of fins 3 are arranged side by side in the second direction Y.

Each of the heating elements H is directly or indirectly in contact with one surface of the base portion 2 on the other side Z2 in the third direction. The heating element H is superimposed on the plurality of fins 3 as viewed from the third direction Z. A refrigerant flows along the first direction X between the plurality of fins 3 adjacent to each other in the second direction Y. As a result, the refrigerant absorbs heat from the heating elements H via the base portion 2 and the plurality of fins 3. The refrigerant is, for example, water or an ethylene glycol aqueous solution. In this manner, the cooling structure 1 cools the heating elements H.

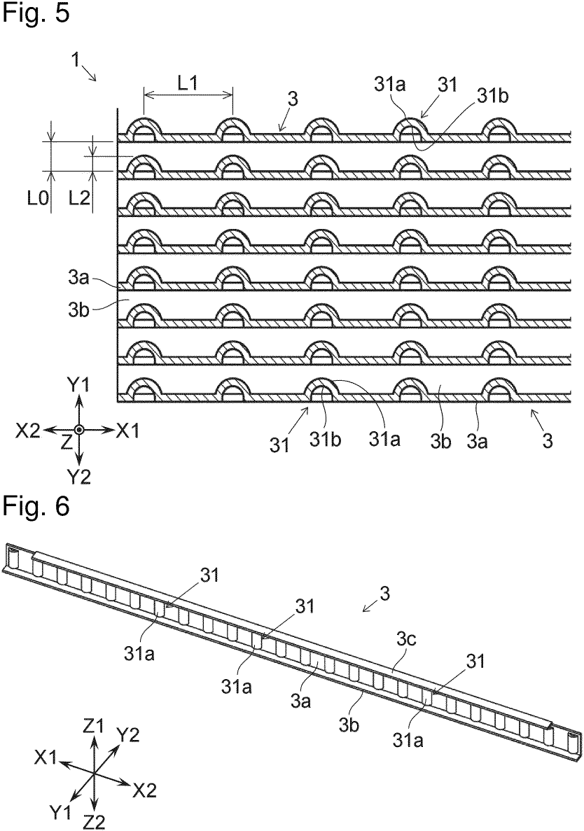

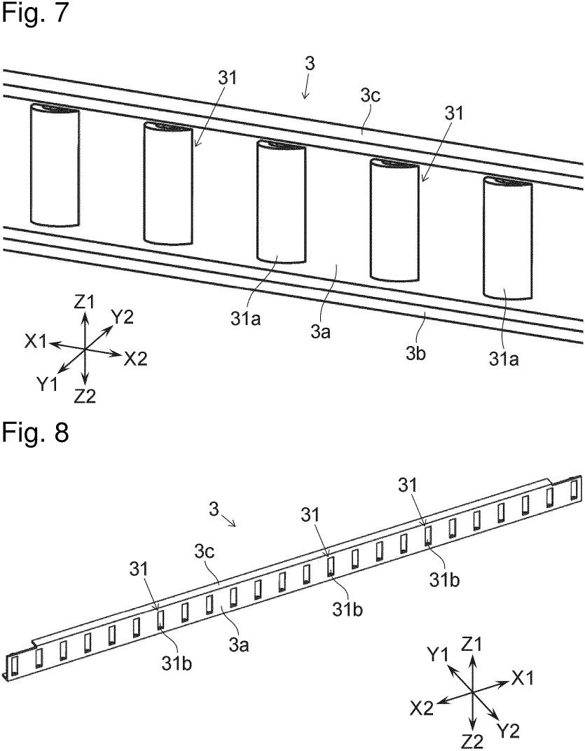

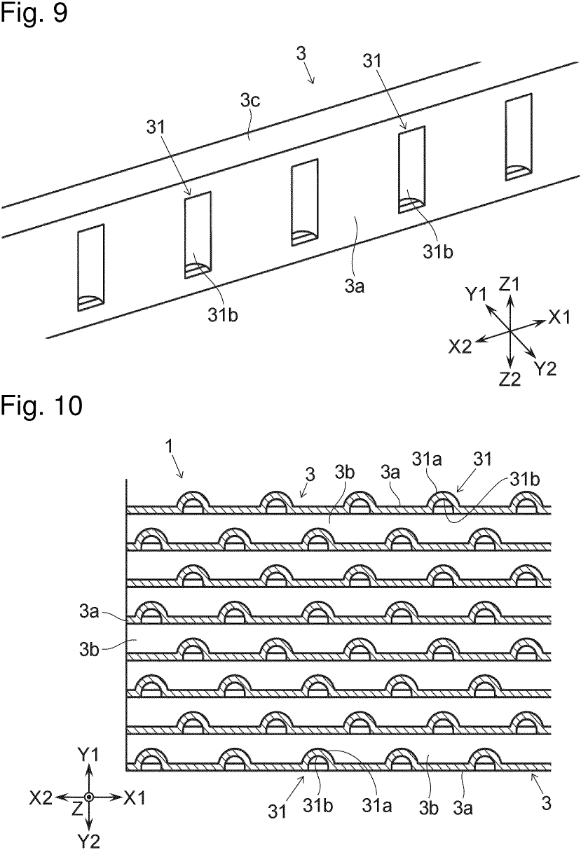

FIG. 5 is a partially enlarged cross-sectional view of the cooling structure 1. FIGS. 6 and 7 are a perspective view and a partially enlarged perspective view of the fin 3 as viewed from one side Y1 in the second direction respectively. FIGS. 8 and 9 are a perspective view and a partially enlarged perspective view of the fin 3 as viewed from the other side Y2 in the second direction respectively.

As described above, each of the fins 3 extends in the first direction X and the third direction Z. With respect to the third direction Z, the fin 3 extends longer in the first direction X in which the refrigerant flows. Each of the fins 3 includes a wall part 3a, a bottom plate part 3b, and a top plate part 3c.

The wall part 3a has a plate shape extending in the first direction X and the third direction Z and having a thickness in the second direction Y. The bottom plate part 3b is formed by being bent from an end portion of the wall part 3a on the other side Z2 in the third direction toward the one side Y1 in the second direction. The top plate part 3c is formed by being bent from an end portion of the wall part 3a on the one side Z1 in the third direction toward the one side Y1 in the second direction. The bottom plate part 3b and the top plate part 3c are opposed to each other in the third direction Z. As a result, the fin 3 has a channel shaped cross section as viewed from the first direction X.

Tip portions of the bottom plate part 3b and the top plate part 3c in the second direction Y are in contact with the wall part 3a of another fin 3 adjacent in the second direction Y. As a result, a closed space surrounded by the two wall parts 3a of the fins 3 adjacent to each other in the second direction Y and the bottom plate part 3b and the top plate part 3c of one of the fins 3 is formed. The refrigerant flows in the closed space along the first direction X. A cover member 4 formed of only a portion corresponding to the wall part 3a is disposed at an end portion of the plurality of fins 3 on the one side Y1 in the second direction (refer to FIG. 3).

Each of the plurality of fins 3 has curved portions 31. The curved portions 31 are disposed on the wall part 3a of the fin 3. Each curved portion 31 is formed of a convex portion 31a and a concave portion 31b opposed to each other in the second direction Y.

The curved portion 31 is curved due to the convex portion 31a and the concave portion 31b disposed at the same position in the first direction X. The convex portion 31a protrudes to the one side Y1 in the second direction. The concave portion 31b is recessed from the other side Y2 in the second direction to the one side Y1 in the second direction. The curved portion 31 is formed by, for example, pressing the wall part 3a of the fin 3.

According to the above configuration, the integrated curved portion 31 is easily formed by press working or the like on the fin 3 extending in the first direction X in which the refrigerant flows. When the refrigerant collides with the curved portion 31, a temperature boundary layer developed on a side surface of the wall part 3a extending in the first direction X is broken, and a heat transfer characteristic is improved. Thus, it is possible to ensure effective cooling performance by the configuration in which the cost is reduced.

As illustrated in FIG. 5, each of the plurality of fins 3 has the plurality of curved portions 31 arranged side by side in the first direction X. In the present example embodiment, the plurality of curved portions 31 are arranged side by side at equal intervals every distance L1 in the first direction X, for example. According to this configuration, the temperature boundary layer developed on the side surface of the wall part 3a is broken and generation of a turbulent flow is promoted. As a result, the heat transfer characteristic is further improved, and the cooling performance is improved.

Further, as illustrated in FIG. 5, the plurality of curved portions 31 are curved toward the one side Y1 in the second direction. That is, the plurality of curved portions 31 are curved in the same direction of the second direction Y. According to this configuration, the plurality of curved portions 31 are easily formed on the fin 3.

In addition, as illustrated in FIG. 5, each of the plurality of fins 3 is formed of a member having the same shape. As a result, the curved portions 31 are disposed at the same positions in the first direction X on each of the plurality of fins 3. In other words, the curved portions 31 are arranged along the second direction Y between the plurality of fins 3. According to the above configuration, it is possible to form a flow path in which the cooling performance is improved by arranging the fins 3 having the same shapes, and it is possible to suppress an increase in cost.

In addition, as illustrated in FIGS. 5 to 9, the curved portion 31 has a semicircular shape as viewed from the third direction Z. Further, the curved portion 31 has a rectangular shape as viewed from the second direction Y. That is, the curved portion 31 has a semi-cylindrical shape obtained by dividing a cylinder extending in the third direction Z along the first direction X and the third direction Z. According to this configuration, the generation of the turbulent flow is promoted over an entire region in the third direction Z on the side surface of the wall part 3a of the fin 3, and the heat transfer characteristic is improved.

FIG. 10 is a partially enlarged cross-sectional view of a cooling structure 1 according to a first modification. The cooling structure 1 of the first modification includes a plurality of fins 3. Each of the plurality of fins 3 has a plurality of curved portions 31. The curved portions 31 are disposed at the same positions in the first direction X in each of the plurality of fins 3 arranged alternately side by side in the second direction Y.

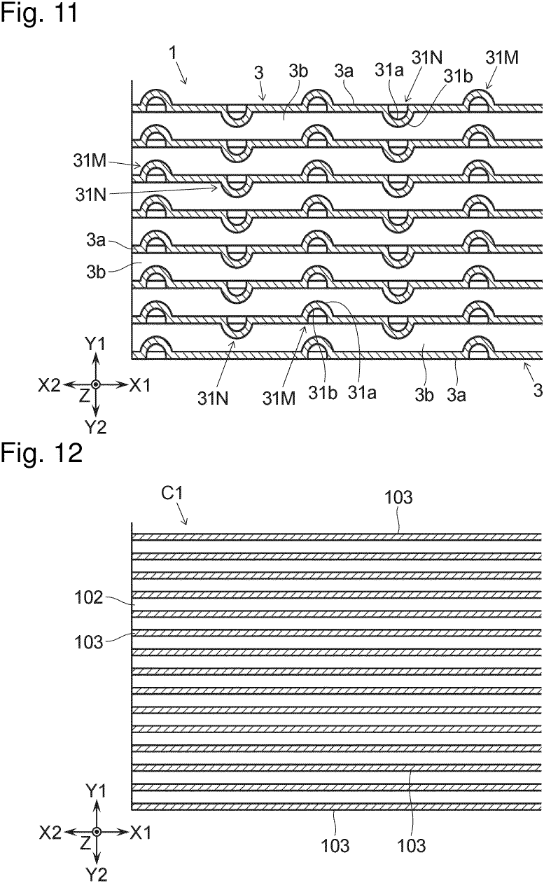

FIG. 11 is a partially enlarged cross-sectional view of a cooling structure 1 according to a second modification. The cooling structure 1 of the second modification includes a plurality of fins 3. Each of the plurality of fins 3 has a plurality of curved portions 31. In the plurality of curved portions 31, a curved portion 31M curved to the one side Y1 in the second direction and a curved portion 31N curved to the other side Y2 in the second direction are alternately arranged in the first direction X.

With respect to the cooling performance of the cooling structure according to the present disclosure, an influence of the configuration of the cooling structure on a maximum temperature of the heating element and a pressure loss of the refrigerant is evaluated hereinafter. The result will be described with reference to FIGS. 12 to 18. The cooling portions 1 according to the example embodiment (Ex), the first modification (Ev1), and the second modification (Ev2) of the present disclosure have the configurations described above with reference to FIGS. 1 to 11.

FIGS. 12, 13, and 14 are partially enlarged cross-sectional views of cooling portions of a first comparative example (C1), a second comparative example (C2), and a third comparative example (C3) respectively.

As illustrated in FIG. 12, the cooling structure of the first comparative example (C1) has a plurality of fins 103 with respect to a base portion 102. The fin 103 has a plate shape extending in the first direction X and the third direction Z. With respect to the third direction Z, the fin 103 extends longer in the first direction X in which the refrigerant flows. The plurality of fins 103 are arranged side by side at predetermined intervals in the second direction Y. The refrigerant passes between the plurality of fins 103 adjacent to each other in the second direction Y and flows along the first direction X.

As illustrated in FIG. 13, the cooling structure of the second comparative example (C2) has a plurality of fins 203 with respect to a base portion 202. The fin 203 is a so-called pin fin having a columnar shape extending in the third direction Z. The plurality of fins 203 are arranged side by side at intervals in the first direction X and the second direction Y. The refrigerant passes between the plurality of fins 203 adjacent to each other in the first direction X and the second direction Y and flows along the first direction X.

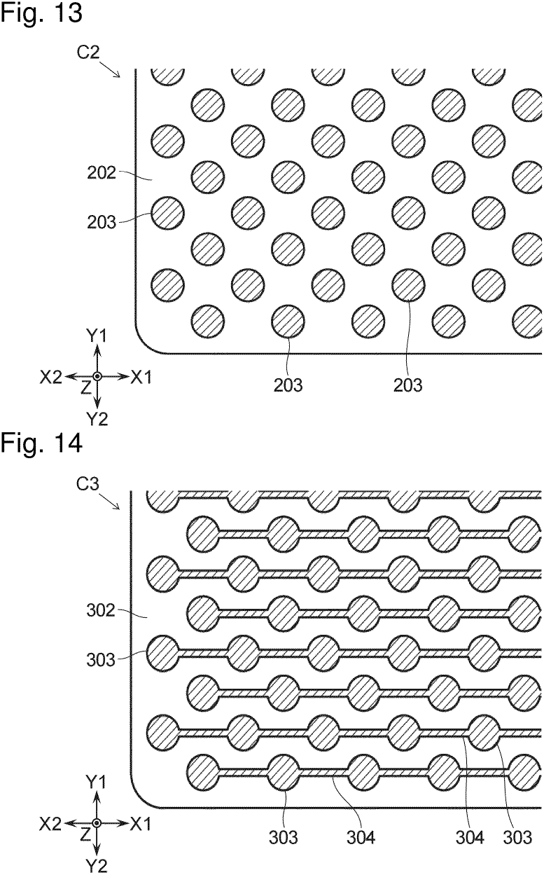

As illustrated in FIG. 14, the cooling structure of the third comparative example (C3) has a plurality of fins 303 and a plurality of partitions 304 with respect to a base portion 302. The fin 303 is a so-called pin fin having a columnar shape extending in the third direction Z. The plurality of fins 303 are arranged side by side at intervals in the first direction X and the second direction Y. The partition 304 has a plate shape extending in the first direction X and the third direction Z. The partition 304 connects the two fins 303 adjacent to each other in the first direction X. The refrigerant is divided by the plurality of fins 303 and the plurality of partitions 304, passes through each gap extending along the first direction X, and flows along the first direction X.

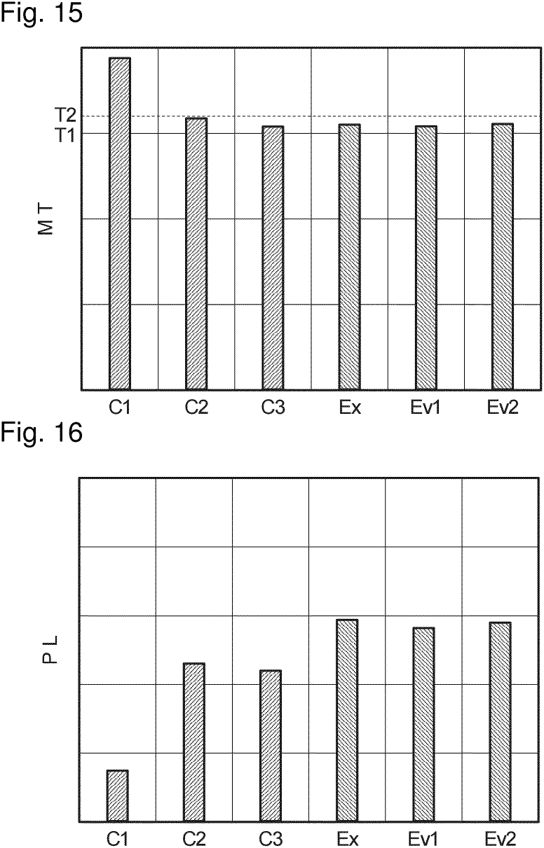

FIG. 15 is a graph illustrating the maximum temperature of the heating element of the cooling structure of each of the example embodiment, the modifications, and the comparative examples. Results of the maximum temperature of the heating element by simulation are shown in FIG. 15. A horizontal axis in FIG. 15 indicates the results of the cooling portions of the first comparative example (C1), the second comparative example (C2), and the third comparative example (C3) and of the cooling portions 1 of the example embodiment (Ex), the first modification (Ev1), and the second modification (Ev2) according to the present disclosure. A vertical axis “MT” in FIG. 15 is the maximum temperature of the heating element, and indicates that the temperature is higher as going upward.

According to FIG. 15, it turns out that each of the cooling portions of the second comparative example (C2) and the third comparative example (C3) having the pin fins has a lower maximum temperature of the heating element and higher cooling performance than the cooling structure of the first comparative example (C1) configured only with the plate-shaped fins 103. The cooling portions of the second comparative example (C2) and the third comparative example (C3) show that the cooling performance for the heating element is improved by providing the pin fins.

On the other hand, it turns out that each of the cooling portions 1 of the example embodiment (Ex), the first modification (Ev1), and the second modification (Ev2), similarly to the cooling portions of the second comparative example (C2) and the third comparative example (C3), has the low maximum temperature of the heating element and the high cooling performance. The cooling portions 1 of the example embodiment (Ex), the first modification (Ev1), and the second modification (Ev2) show that the cooling performance for the heating element is improved, similarly to the cooling portions of the comparative examples having the pin fins, by providing the curved portions 31 on the fin 3. Thus, it is possible to ensure effective cooling performance by the configuration in which the cost is reduced.

FIG. 16 is a graph illustrating the pressure loss of the refrigerant of the cooling structure of each of the example embodiment, the modifications, and the comparative examples. Results of the pressure loss of the refrigerant by simulation are shown in FIG. 16. A horizontal axis in FIG. 16 indicates the results of the cooling portions of the first comparative example (C1), the second comparative example (C2), and the third comparative example (C3) and of the cooling portions 1 of the example embodiment (Ex), the first modification (Ev1), and the second modification (Ev2) according to the present disclosure. A vertical axis “PL” in FIG. 16 indicates the pressure loss of the refrigerant, and indicates that the loss increases as going upward.

It is shown in FIG. 16 that the cooling structure according to the first comparative example (C1) configured only with the plate-shaped fins 103 has the lowest pressure loss of the refrigerant. It turns out that each of the cooling portions of the second comparative example (C2) and the third comparative example (C3) has the higher pressure loss of the refrigerant than the cooling structure of the first comparative example (C1) by having the pin fins. However, considering the cooling performance for the heating element (refer to FIG. 15), the pressure loss is within an allowable range.

The pressure loss of the refrigerant in the cooling structure 1 of each of the example embodiment (Ex), the first modification (Ev1), and the second modification (Ev2) is substantially the same as that of the cooling structure of each of the second comparative example (C2) and the third comparative example (C3). That is, each of the cooling portions 1 of the example embodiment (Ex), the first modification (Ev1), and the second modification (Ev2) has the pressure loss of the refrigerant within the allowable range, and is capable of ensuring the effective cooling performance with the configuration in which the cost is lower than that of the cooling structure of each of the comparative examples.

It is to be noted that, as illustrated in FIG. 10, the curved portions 31 of the cooling structure 1 according to the first modification (Ev1) are disposed at the same positions in the first direction X in each of the plurality of fins 3 arranged alternately side by side in the second direction Y. As shown in FIG. 11, in the plurality of curved portions 31 of the cooling structure 1 of the second modification (Ev2), the curved portions 31M curved to the one side Y1 in the second direction and the curved portions 31N curved to the other side Y2 in the second direction are alternately arranged in the first direction X. Even in the above modifications, it is possible to ensure the effective cooling performance by the configuration in which the cost is reduced.

The cooling structure 1 of the present disclosure has, for example, a shape of fin 3 shown in FIG. 5. The fins 3 adjacent to each other in the second direction Y have an interval L0. The curved portions 31 adjacent to each other in the first direction X have a distance L1. The curved portion 31 protrudes in the second direction Y by the protrusion amount L2 with respect to the wall part 3a. The fin 3 of the cooling structure 1 according to the example embodiment (Ex) illustrated in FIG. 5 is taken as a representative, and effect of changing the fin shape is evaluated hereinafter.

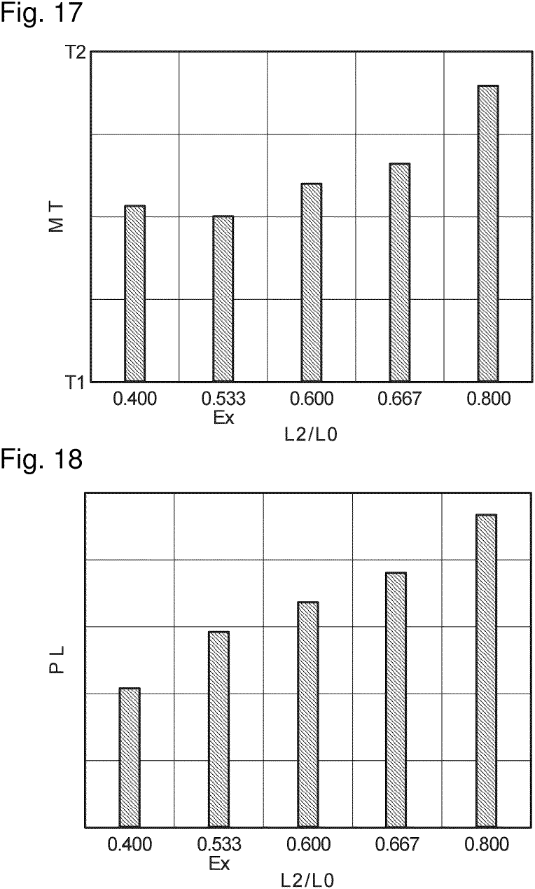

FIG. 17 is a graph illustrating the maximum temperature of the heating element H when the fin shape of the cooling structure 1 according to the example embodiment is changed. Results of the maximum temperature of the heating element by simulation are illustrated in FIG. 17. Specifically, in the fin 3 (refer to FIG. 5) of the cooling structure 1 according to the example embodiment (Ex) of the present disclosure, a ratio “L2/L0” of the protrusion amount L2 of the curved portion 31 in the second direction Y to the interval L0 between the fins 3 adjacent to each other in the second direction Y is changed. A horizontal axis in FIG. 17 is “L2/L0” of the fin 3, and the evaluation is performed for 5 types. The example embodiment (Ex) of the present disclosure has L2/L0 = 0.533. A vertical axis “MT” in FIG. 17 is the maximum temperature of the heating element and corresponds to a range from the temperature T1 to T2 illustrated in FIG. 15.

According to FIG. 17, it turns out that the cooling structure 1 of the example embodiment (Ex, L2/L0 = 0.533) has the lowest maximum temperature of the heating element and the high cooling performance. Then, it tuns out that, when L2/L0 = 0.600 or more, the maximum temperature of the heating element gradually increases. As a result, with respect to the maximum temperature of the heating element, “L2/L0” of the fin 3 is preferably 0.54 or less.

FIG. 18 is a graph illustrating the pressure loss of the refrigerant when the fin shape of the cooling structure 1 according to the example embodiment is changed. Results of the pressure loss of the refrigerant by simulation are illustrated in FIG. 18. Similarly to FIG. 17, a horizontal axis in FIG. 18 is “L2/L0” of the fin 3, and the evaluation is performed for 5 types. A vertical axis “PL” in FIG. 18 indicates the pressure loss of the refrigerant, and indicates that the loss increases as going upward.

According to FIG. 18, it turns out that the pressure loss of the refrigerant increases as “L2/L0” of the fin 3 increases. That is, it turns out that the pressure loss of the refrigerant increases as the protrusion amount L2 of the curved portion 31 with respect to the wall part 3a of the fin 3 increases. As a result, with respect to the pressure loss of the refrigerant, “L2/L0” of the fin 3 is preferably as small as possible.

From the evaluation based on FIGS. 17 and 18, the cooling structure 1 satisfies the following expressions (1) and (2) when the interval between the fins 3 adjacent to each other in the second direction Y is denoted by L0, the distance between the curved portions 31 adjacent to each other in the first direction X is denoted by L1, and the protrusion amount of the curved portion 31 in the second direction Y is denoted by L2.

$$\text{L1/L0} \geq 3 \qquad \text{(1)}$$

$$\text{L2/L0} \leq 0.54 \qquad \text{(2)}$$

All the cooling portions 1 of the example embodiment (Ex), the first modification (Ev1), and the second modification (Ev2) are configured based on conditions according to the above two expressions. According to the above configuration, the cooling performance is improved without preventing the flow of the refrigerant between the fins 3 adjacent to each other in the second direction Y.

The example embodiment according to the present disclosure has been described above. It is to be noted that the scope of the present disclosure is not limited to the above. It is to be understood that the present disclosure may be implemented by adding, omitting, and replacing configurations and various other modifications without departing from the spirit of the present disclosure. It is to be further understood that the above-described example embodiment and modifications may be appropriately and arbitrarily combined within a range where no inconsistency occurs.

For example, a vapor chamber or a heat pipe may be provided between the heating element and the cooling structure.

The present disclosure is capable of being used for cooling various heating elements.

Features of the above-described preferred example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling structure comprising:
a base that has a plate shape, that extends in a first direction along a refrigerant flow direction and in a second direction perpendicular or substantially perpendicular to the first direction, and that includes a thickness in a third direction perpendicular or substantially perpendicular to the first direction and the second direction; and
fins that protrude from the base to one side in the third direction, that extend in the first direction, and that are arranged side by side in the second direction; wherein
each of the fins includes a curved portion that is curved due to a convex portion, protruding to one side in the second direction, and a concave portion, recessed from another side to the one side in the second direction, located at a same position in the first direction.

2. The cooling structure according to claim 1, wherein the each of the fins includes a plurality of the curved portions arranged side by side in the first direction.

3. The cooling structure according to claim 2, wherein the plurality of curved portions are curved in a same direction of the second direction.

4. The cooling structure according to claim 2, wherein in the plurality of curved portions, the curved portion curved to the one side in the second direction and the curved portion curved to the other side in the second direction are alternately arranged in the first direction.

5. The cooling structure according to claim 2, wherein when an interval between the fins adjacent to each other in the second direction is denoted by L0, a distance between the curved portions adjacent to each other in the first direction is denoted by L1, and a protrusion amount of the curved portion in the second direction is denoted by L2, expressions (1) and (2) are satisfied:
$$\text{L} 1 / \text{L} 0 \geq 3 \qquad \text{(1)}$$
$$\text{L} 2 / \text{L} 0 \leq 0.54 \qquad \text{(2)}$$
.

6. The cooling structure according to claim 1, wherein the curved portion is at a same position in the first direction in the each of the fins.

7. The cooling structure according to claim 1, wherein the curved portion is at a same position in the first direction in the each of the fins arranged alternately side by side in the second direction.

8. The cooling structure according to claim 1, wherein the curved portion has a semicircular shape or substantially semicircular shape as viewed from the third direction and a rectangular or substantially rectangular shape as viewed from the second direction.
